(19) United States
(12) Patent Application Publication
(10) Pub. No.: US 2004/0102017 A1
(43) Pub. Date: May 27, 2004

(54) Method of forming trench isolation structure

(76) Inventors: Tsz-Lin Chang, Taipei (TW); Wen-Pin Chiu, Yunlin (TW)

Correspondence Address: BIRCH STEWART KOLASCH & BIRCH, PO BOX 747, FALLS CHURCH, VA, 22040-0747, US

(21) Appl. No.: 10/389,770

(22) Filed: Mar. 18, 2003

(30) Foreign Application Priority Data
Nov. 27, 2002 (TW) 091134451

(51) Int. Cl. H01L 21/76

(52) U.S. Cl. 438/424

(57) ABSTRACT

A method to form a trench isolation structure. Pre-amorphization is performed on the surface of a trench before liner oxidation, and particularly with the amorphization for the silicon crystals performed by quad ion implantation. Formation of the liner using the present method lowers process temperature and shortens process time.

### BACKGROUND OF THE INVENTION

1. Field of the Invention

The present invention relates to a method of forming a trench isolation structure in semiconductor devices, wherein pre-amorphization is performed on the surface of trench before liner oxidation is performed.

2. Description of the Related Art

Among different semiconductor device manufacturing techniques, especially for sub 0.25 μm integrated circuits, shallow trench isolation manufacturing techniques are gradually replacing LOCOS methods. A conventional manufacturing method for shallow trench isolation structure is shown in the cross-section of FIG. 1.

First, a pad oxide layer 2 and a silicon nitride layer 3 are sequentially formed on a silicon substrate 1, and then patterned by lithography to expose the portion where the isolation structure is to be formed. After the pad oxide layer, the silicon nitride layer, and the silicon substrate are sequentially etched according to the pattern, a trench 4 is formed.

Next, thermal oxidation is performed to grow a liner oxide layer 5 on the surface of the trench 4. Then, chemical vapor deposition (CVD) is performed to fill an oxide layer 6 in the trench 4. Thereafter, chemical mechanical polishing (CMP) is performed, whereby the excess oxide layer 6 on the surface is removed, with the silicon nitride layer 3 as a polish stop, to provide a planar surface. Finally, the silicon nitride layer 3 and the pad oxide layer 2 are removed to allow subsequent manufacture of other elements and the shallow trench isolation structure is formed.

Nevertheless, the process temperature used in the conventional thermal oxidation method to form a liner oxide layer on the surface of trench is high and the process time is long. Although the process time can be as short as tens of seconds when rapid thermal process (RTP) is used for the oxidation, the process temperature needed can be as high as 1100° C. to 1150° C. Therefore, in the manufacture of liner oxide layer on the surface of trench, there is still a need for methods which can reduce heat budget and shorten process time.

### SUMMARY OF THE INVENTION

Accordingly, an object of the invention is to provide a method of forming a trench isolation structure in the semiconductor device process, wherein the surface of a trench is pre-amorphized before the liner oxide layer is formed, in order to reduce the heat budget and shorten the process time for the formation of the liner oxide layer.

Another object of the invention is to provide a method of forming a trench isolation structure in the semiconductor device process, wherein the surface of trench is pre-amorphized by O₂ quad ion implantation before the liner oxide layer is formed, in order to reduce the heat budget and shorten the process time for the formation of the liner oxide layer.

To achieve the objects mentioned above, the invention provides a method of forming a trench isolation structure. First, a substrate covered by a mask layer is provided. Next, the mask layer and the substrate are etched to form a trench. Next, pre-amorphization is performed on the bottom and sidewalls of the trench. Then, thermal oxidation on the substrate is performed to form a liner oxide layer on the bottom and sidewalls of the trench. Thereafter, an insulating layer is filled in the trench to form a trench isolation structure.

Furthermore, the invention also provides another method of forming a trench isolation structure. First, a substrate covered by a pad oxide layer and a nitride layer is provided. Next, the nitride layer, the pad oxide layer, and the substrate are etched to form a trench. Next, pre-amorphization is performed on the bottom and sidewalls of the trench by, preferably, O₂ quad ion implantation. Then, thermal oxidation on the substrate is performed to form a liner oxide layer on the bottom and sidewalls of the trench. Thereafter, an insulating layer is filled in the trench to form a trench isolation structure.

The present invention saves manufacturers of semiconductor devices considerable energy and time.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a cross-section showing a conventional method of forming a trench isolation structure; and

FIGS. 2a through 2d are cross-sections showing a method of forming a trench isolation structure according to the present invention.

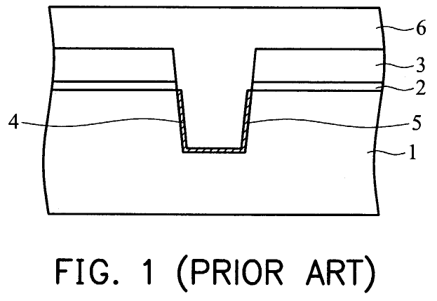

### DETAILED DESCRIPTION OF THE INVENTION

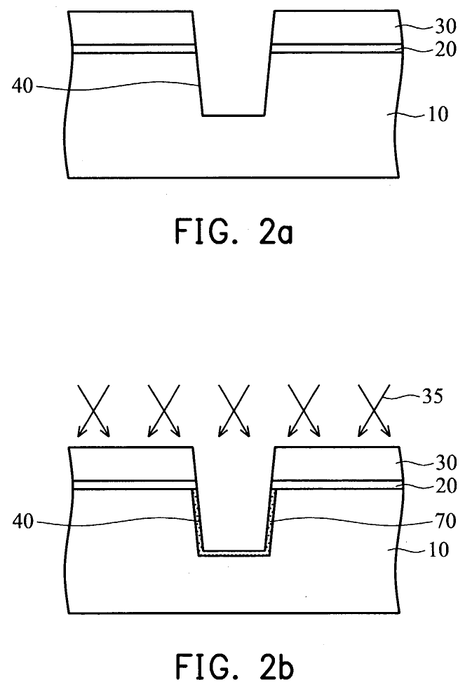

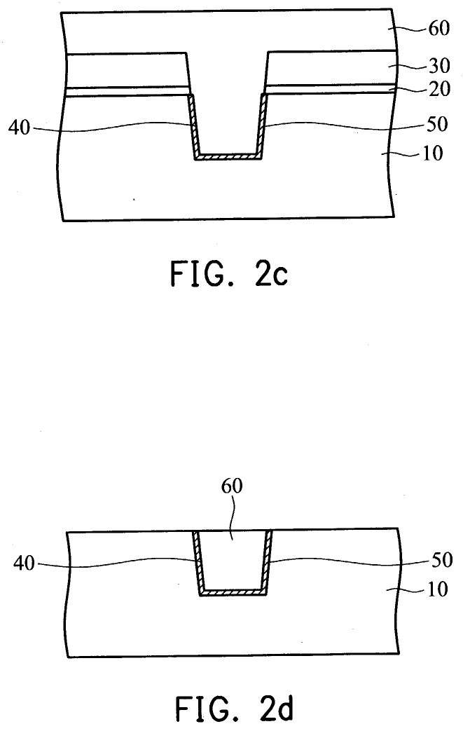

A preferred embodiment of the present invention is now described with reference to FIGS. 2a to 2d.

First, in FIG. 2a, a semiconductor substrate, such as a silicon wafer 10, is provided. A mask layer is formed on the substrate 10. The mask layer preferably has a thickness of about 200˜3500 Å and can be a monolayer or stacked layers. The mask layer is preferably composed of a pad oxide layer 20 and a thicker silicon nitride layer 30. The pad oxide layer can be formed by thermal oxidation or conventional CVD, such as atmospheric pressure CVD (APCVD) or low pressure CVD (LPCVD). The silicon nitride layer 30 overlying the pad oxide layer 20 can be formed by LPCVD using SiCl₂H₂ and NH₃ as reaction source. Next, a photoresist layer (not shown) is coated on the mask layer. Thereafter, lithography is performed on the photoresist layer to form an opening (not shown). The opening defines trench isolation region.

Thereafter, the photoresist layer having the opening is used as a mask to anisotropically etch the mask layer by, for example, reactive ion etching (RIE) or high density plasma (HDP) etching, to transfer the pattern of the photoresist layer to the mask layer and form an opening inside.

Next, suitable wet etching or ashing is performed to remove the photoresist layer. Subsequently, anisotropic etching is performed by, for example, the RIE, with the mask layer as an etch mask. The silicon substrate 10 under the opening is etched to a predetermined depth, such as 3000˜6000 Å, to form a trench 40 in the silicon substrate 10, as shown in FIG. 2a.

Next, FIG. 2b shows the critical step of the invention's amorphization on the bottom and sidewalls of trench 40. The goal for the critical step is to accomplish pre-amorphization of crystals on the surface of trench before the step of thermal oxidation is performed. Materials suitable for the substrate in the invention are, for example, semiconductor materials from group IV, group III-V, or group II-VI of the periodic table, such as silicon, germanium, gallium arsenide, indium phosphide, or zinc selenide. Suitable amorphization processes are exemplified by ion implantation and plasma to amorphize the surface, with the most preferable being quad ion implantation.

The ion sources used may be oxygen, nitrogen, inert gasses (such as helium, neon, argon, and krypton), group IV elements in the periodic table (such as silicon, germanium), or elements which compose the substrates. In view of the process of forming liner oxide layer, oxygen is preferred. The dose and the energy used vary according to the ion used or the liner oxide layer to be formed. For example, when oxygen ion source is used, the energy used ranges from about 1 to about 20 keV, preferably from about 3 to about 8 keV. The dosage used ranges from about 5×10¹⁵ to about 5×10¹⁶ cm⁻². The incident ion beam tilts at a certain angle measured from a normal to the surface of the substrate. The wafer bearing the surface of trench is rotated in four steps at a rotation angle of 90 degrees in each step, and the surface of the substrate is, therefore, ion implanted at wafer rotation angles of 0 (initially), 90, 180, and 270 degrees, respectively. The angle of tilt depends on the profile of the trench. By adjusting the tilt angle in addition to the four-step rotation, the bottom and side wall of the trench can be easily ion implanted to effect the amorphization of the crystals on the surface, as shown in FIG. 2b. If the general ion implantation process is used, the ions relatively vertically bombard the trench and cannot effectively reach the side walls or the angles formed by the bottom and the side walls, thus, the amorphization in this kind of area cannot be easily accomplished. When the quad ion implantation is performing, the ions also attack the part of nitride layer 30. This will not affect the result of the invention because the nitride layer is removed at the end of the process.

Thermal oxidation is then performed using oxygen (O₂) or other oxidation gas, such as ozone (O₃), to form a liner oxide layer 50. During oxidation, the surface of the trench on which pre-amorphization has been performed is rougher and allows oxygen atoms to travel along grain boundaries to form a fine oxidation structure on the surface, resulting in an oxide layer with better quality. In addition, in the case of low energy O₂ implantation, the rougher surface and the implanted oxygen atoms, compared to the conventional method without pre-amorphization, are advantageous to the formation of oxide layer, because the process temperature is lower and the process time is shorter. Therefore, the liner oxide layer with the same thickness (generally about 100˜300 Å) desired can be achieved in a shorter time, and the temperature used in rapid thermal process under a generally process pressure, about 1 atm, can be reduced to about 900 to 1000° C.

When high temperature oxidation, a conventional method of forming a trench isolation structure, is employed without the step of pre-amorphization to form a liner oxide layer on the surface of trench 4 through the oxidation of the silicon layer on the surface of trench by oxygen or other oxidizing gas, for example, ozone, the process temperature needed to form liner oxide layer is higher than in the present invention. For example, the processing temperature needed in RTP is about 1100˜1150° C. under a process pressure of about 1 atm. Thus, when the temperature is 1120° C. and the flow rate of oxygen is 5 slm, it takes about 33 seconds to form a liner oxide layer having a thickness of 8 nm. To obtain the same thickness under the same conditions by the method according to the present invention, the temperature needed is only 980° C.

After the liner oxide layer is formed, trench 40 is sufficiently filled with oxide layer 60 deposited from the reaction of TEOS/ozone or SiH₄/O₂ by chemical vapor deposition (CVD), such as sub-atmospheric chemical vapor deposition or high density plasma chemical vapor deposition, and a trench isolation structure is formed, as shown in FIG. 2c.

Next, the excess oxide layer 60 over nitride layer 30 can be removed by etching or chemical mechanical polishing (CMP), with the nitride layer 30 as a polish stop, to form a planar surface. Finally, the mask layer (nitride layer 30 and pad oxide layer 20) is removed to allow subsequent manufacture of the devices, as shown in FIG. 2d. The method of removing the nitride layer 30 can be wet etching, for example, soaking the nitride layer with hot H₃PO₄. The method of removing pad oxide layer 20 can be wet etching, for example, soaking the pad oxide layer with HF liquid.

The foregoing description has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of forming a trench isolation structure, comprising the steps of:
providing a substrate;
forming a mask layer on the substrate;
etching the mask layer and the substrate to form at least one trench;
performing pre-amorphization on the bottom and sidewalls of the trench;
performing thermal oxidation on the substrate to form a liner oxide layer on the bottom and sidewalls of the trench; and
filling an insulating layer in the trench to form a trench isolation structure.

2. The method as claimed in claim 1, wherein the pre-amorphization is accomplished by ion implantation or by use of plasma.

3. The method as claimed in claim 2, wherein the ion implantation is quad ion implantation.

4. The method as claimed in claim 3, wherein the ion source used in the quad ion implantation is O₂, N₂, inert gas, germanium, or silicon.

5. The method as claimed in claim 4, wherein the ion source used in the quad ion implantation is O₂.

6. The method as claimed in claim 5, wherein the energy used for O₂ implantation is from 1 to 20 keV.

7. The method as claimed in claim 1, wherein the rapid thermal process is employed in the thermal oxidation.

8. The method as claimed in claim 7, wherein the temperature used in the rapid thermal process is from 900 to 1000° C.

9. The method as claimed in claim 1, wherein the mask includes a pad oxide layer and a nitride layer.

10. The method as claimed in claim 1, wherein the insulating layer is filled in the trench by high density plasma chemical vapor deposition or sub-atmospheric chemical vapor deposition.

11. A method of forming a trench isolation structure, comprising the steps of:
providing a substrate;
forming a pad oxide layer and a nitride layer in the order on the substrate;
etching the nitride layer, the pad oxide layer, and the substrate to form at least one trench;
performing O₂ quad ion implantation on the bottom and sidewalls of the trench;
performing thermal oxidation on the substrate to form a liner oxide layer on the bottom and sidewalls of the trench; and
filling an insulating layer in the trench to form a trench isolation structure.

12. The method as claimed in claim 11, further comprising, after forming the trench isolation structure, the steps of:
removing the insulating layer and liner oxide layer over the nitride layer by chemical mechanical polishing; and
removing the nitride layer and the pad oxide layer by etching.

13. The method as claimed in claim 11, wherein the energy used for O₂ quad ion implantation is from 1 to 20 keV.

14. The method as claimed in claim 11, wherein the rapid thermal process is employed in the thermal oxidation.

15. The method as claimed in claim 14, wherein the temperature used in the rapid thermal process is from 900 to 1000° C.

16. The method as claimed in claim 11, wherein the insulating layer is filled in the trench by high density plasma chemical vapor deposition or sub-atmospheric chemical vapor deposition.
